(19) United States
(12) Patent Application Publication
(10) Pub. No.: US 2015/0318452 A1
(43) Pub. Date: Nov. 5, 2015

(54) LED PACKAGE STRUCTURE FOR ENHANCING MIXED LIGHT EFFECT

(71) Applicant: UNITY OPTO TECHNOLOGY CO., LTD., New Taipei City (TW)

(72) Inventors: PING-CHEN WU, NEW TAIPEI CITY (TW); HUAN-YING LU, NEW TAIPEI CITY (TW); SHIH-CHAO SHEN, NEW TAIPEI CITY (TW)

(21) Appl. No.: 14/798,466

(22) Filed: Jul. 14, 2015

Related U.S. Application Data
(63) Continuation-in-part of application No. 13/464,101, filed on May 4, 2012.

(30) Foreign Application Priority Data
Nov. 11, 2011 (TW) 100141242

(51) Int. Cl. H01L 33/50; H01L 27/15; F21K 99/00

(52) U.S. Cl. CPC H01L 33/504; F21K 9/54; F21K 9/56; H01L 27/153

(57) ABSTRACT

An LED package structure for enhancing mixed light effect comprises: at least one first light emitting chip; at least one second light emitting chip, a frame structure having a first containing portion, a second containing portion, a spacing portion and a light mixing area; a first colloid, filled into the first containing portion; a second colloid, filled into the second containing portion; and an encapsulating colloid, packaged and filled into the light mixing area. This design can enhance the light emission efficiency and achieve a uniform light-mixing dot light source.

### CROSS-REFERENCE TO RELATED APPLICATIONS

This application is a continuation-in-part patent application of U.S. application Ser. No. 13/464,101 filed on May 4, 2012, the entire contents of which are hereby incorporated by reference for which priority is claimed under 35 U.S.C. §120.

### BACKGROUND OF THE INVENTION

1. Field of the Invention

The present invention relates to a light emitting diode (LED) structure, in particular to an white-light LED structure diode capable of converting some of the light source with a wavelength of 400 nm˜500 nm into a light with a wavelength of 490 nm˜600 nm without affecting the light emission efficiency of the LED with a wavelength of 600 nm˜700nm, and uniformly mixing the lights with different wavelengths to enhance the light mixing effect.

2. Description of the Related Art

In recent years, blue-light LED plus yellow phosphor package has become a mainstream of backlight source of white-light LED, but most yellow phosphor related patents are owned by a Japanese company, Nichia, and LED of these patents have a lower color rendering index, and the white-light LED produced by mixing blue light, red light and green light gains increasingly higher market share.

In present technologies, one or more chip packages can be installed on the same LED as disclosed in U.S. Pat. No. 6,577,073, wherein red-light and blue-light LEDs are installed on the same frame and covered with phosphor, so that after the phosphor is excited by blue light, a green light is emitted, and the green light is mixed with the red light and the blue-light to form a white-light dot light source. However, the red light has relatively lower light emission efficiency and blocked by the phosphor, so that the LED has lower light emission efficiency. Therefore, the LED structural design as disclosed in R.O.C. Pat. No. M380580, but such package structure comes with a complicated process, which is not favorable in mass production.

In view of the aforementioned shortcomings, the present invention provides a simple structure for facilitating the manufacture of LED package structures, and achieves the effects of enhancing the light mixing effect and the light emission efficiency, and providing a white-light dot light source of a higher color rending index.

### SUMMARY OF THE INVENTION

Therefore, it is a primary objective of the present invention to provide an LED package structure, wherein phosphor is coated onto specific areas to improve the effects of exciting and converting light energy, reducing the probability of blocking lights of other wavelengths, and enhancing the overall light emission performance.

To achieve the foregoing objective, the present invention provides an LED package structure for enhancing a mixed light effect, comprising: at least one first light emitting chip, for providing a light source with a wavelength of 400 nm˜500 nm; at least one second light emitting chip, for providing light source with a wavelength of 600 nm˜700 nm; a frame structure, for containing and installing the first light emitting chip and the second light emitting chip, so that the lights passing through the first light emitting chip and the second light emitting chip are mixed to form a white-light dot light source, and the frame structure includes: a first containing portion, being a downwardly tapered cup structure for installing the first light emitting chip; a second containing portion, being a downwardly tapered cup structure for installing the second light emitting chip; a spacing portion, disposed between the first containing portion and the second containing portion, for bonding, connecting and installing the first light emitting chip and the second light emitting chip, for forming a white-light dot light source after the lights emitted from the first light emitting chip and the second light emitting chip are mixed in the light mixing area; a first colloid filled into the first containing portion, for encapsulating the first light emitting chip; a second colloid, filled into the second containing portion, for covering the second light emitting chip; and an encapsulating colloid, packaged and filled into the light mixing area, and disposed on the first colloid and the second colloid.

In view of the directional range of the exit light, the first containing portion and the second containing portion can be designed with a downwardly tapered trapezoid shape. To improve the light mixing and light emitting effects, the first containing portion and the second containing portion can be designed with a downwardly tapered trapezoid shape, and a bottom angle of the trapezoid shape not adjacent to the spacing portion is a right angle.

In the design of the present invention, the phosphor is doped at the top of the light source with the wavelength of 400 nm˜500 nm only, so that the light energy absorption of the phosphor can change the light to a light with a wavelength of 490 nm˜600 nm to increase the range of the wavelength covered by the exiting light, so as to enhance the light rendering performance of the white-light LED, and an exiting light with another wavelength will not be blocked by the phosphor cause a drop of the light emission efficiency, and thus the invention can overcome the drawbacks of the prior art. In addition, the shape of the frame in accordance with the present invention are designed for placing two different LED chips with different wavelengths separately and the dispensing and phosphor coating processes are simple to facilitate mass production.

### BRIEF DESCRIPTION OF THE DRAWINGS

FIG. 1 is a first cross-sectional view of a preferred embodiment of the present invention;

FIG. 2 is a second cross-sectional view of a preferred embodiment of the present invention;

FIG. 3 is a third cross-sectional view of a preferred embodiment of the present invention;

FIG. 4 is a cross-sectional view of another preferred embodiment of the present invention; and

FIG. 5 is a cross-sectional view of an another preferred embodiment of the present invention.

### DETAILED DESCRIPTION OF THE PREFERRED EMBODIMENTS

The technical content of the present invention will become apparent by the detailed description of the following embodiments and the illustration of related drawings as follows.

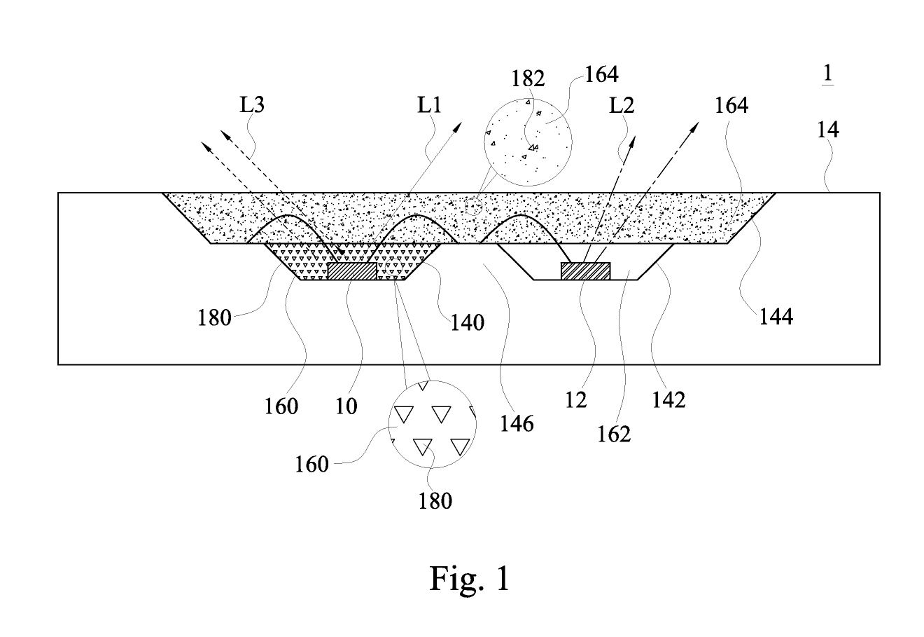

With reference to FIG. 1 for a first cross-sectional view of a white-light LED package structure 1 for enhancing mixed light effect in accordance with a preferred embodiment of the present invention, the white-light LED package structure 1 comprises at least one first light emitting chip 10 and at least one second light emitting chip 12 installed at the bottom of a first containing portion 140 and a second containing portion 142 in a frame structure 14 respectively, and the second containing portion 142 and the first containing portion 140 are downwardly tapered cup structures having a downwardly tapered trapezoid cross-section for installing the first light emitting chip 10 and the second light emitting chip 12, such that the lights emitted from the first light emitting chip 10 and the second light emitting chip 12 are reflected and emitted to enhance the overall light emitting efficiency of the white-light LED. A spacing portion 146 is disposed between the first containing portion 140 and the second containing portion 142 for bonding, connecting and installing the first light emitting chip 10 and the second light emitting chip 12. The first containing portion 140 is filled with a first colloid 160 and covered onto the first light emitting chip 10, and the first colloid 160 is doped with a green-light phosphor 180. When a first light L1 of the first light emitting chip 10 having a wavelength of 400 nm˜500 nm enters into the first colloid 160 to excite the green-light phosphor 180, a third light L3 having a wavelength of 490 nm˜600 nm is emitted. The second containing portion 142 is filled with a second colloid 162 and covered onto the second light emitting chip 12. The first containing portion 140 and the second containing portion 142 have a light mixing area 144 disposed above, and packaged and filled with an encapsulating colloid 164 and situated on the first colloid 160 and the second colloid 162. Since the density of the green-light phosphor 180 doped in the first colloid 160 is adjusted according to an optical design, therefore the light entering from the first containing portion 140 into the light mixing area 144 includes the first light L1 and the third light L3 having two different wavelengths in the ranges of 400 nm˜500 nm and 490 nm˜600 nm respectively, while a second light L2 having a wavelength of 600 nm˜700 nm emitted from the second light emitting chip 12 also enters from the second containing portion 142 into the light mixing area 144, and these lights having three different wavelengths are mixed in the light mixing area 144 to achieve the effect of emitting white light. To enhance the light mixing effect, the encapsulating colloid 164 is doped with a dispersant 182, so that the light entering into the light mixing area 144 will produce optical reactions of diffusion and scattering to provide a more uniformly mixed light for the applications such as backlight and illumination by a white-light light source.

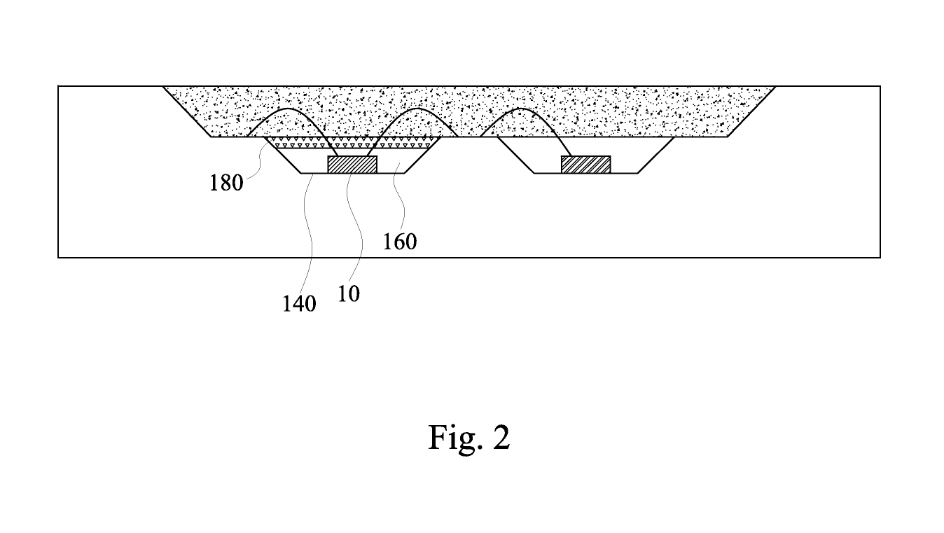

The white-light LED package structure 1 of the present invention is more applicable for two other methods of coating phosphor. Besides the uniform distribution method of uniformly doping in the first colloid 160, a remote phosphor coating method or a conformal coating method can be adopted to dope the green-light phosphor 180 into the first colloid 160. With reference to FIG. 2 for a second cross-sectional view of a preferred embodiment of the present invention, the green-light phosphor 180 is doped into the first colloid 160 by the remote phosphor coating method, so that the green-light phosphor 180 is formed onto a thin layer at the cup opening position of the first containing portion 140, and the light emitted from the first light emitting chip 10 is excited by the green-light phosphor 180 when passing through the thin layer of the green-light phosphor 180 to form lights of two different wavelengths to enhance the light output of a white light LED.

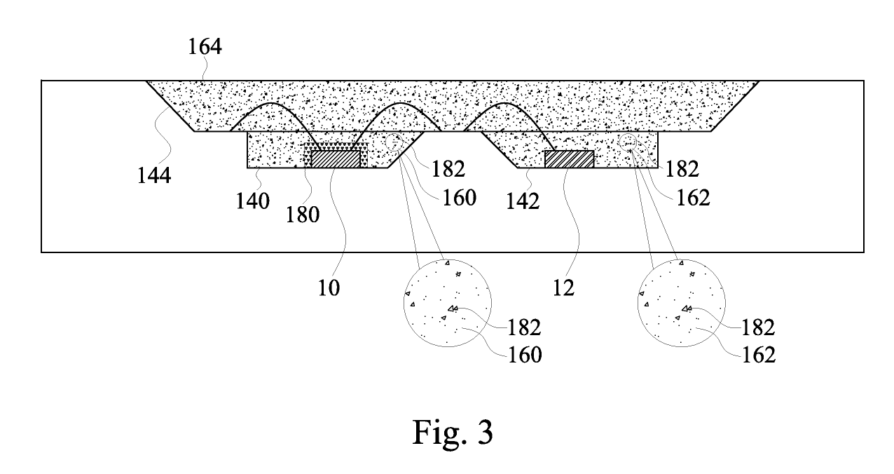

With reference to FIG. 3 for a third cross-sectional view of a preferred embodiment of the present invention, the conformal coating method (by electrophoresis coating method) is adopted to form the green-light phosphor 180 with a uniform thickness onto a surface of the first light emitting chip 10 to totally cover the first light emitting chip 10, such that the light emitted from the first light emitting chip 10 will be excited by the green-light phosphor 180 to change to a light having a different wavelength, and the lights of the two different wavelengths have a longer refraction and diffusion path to achieve the effect of producing a uniform mixed light. Further, the dispersant 182 can be doped into the first colloid 160 and the second colloid 162, so that the light passing through the first containing portion 140, the second containing portion 142 and the light mixing area 144 having the first colloid 160, the second colloid 162 and the encapsulating colloid 164 doped with the dispersant 182 is scattered to improve the uniformity of the LED colors to produce a more uniform white light. To concentrate the light, the first containing portion 140 and the second containing portion 142 can be designed with a specific shape, so that the cross-section of the two containing portions is in a downwardly tapered trapezoid shape, and a bottom angle of the spacing portion 146 is a right angle, and the light emitted from the first light emitting chip 10 and the second light emitting chip 12 is refracted to concentrate the light at a central area to improve the light utility and the light emitting efficiency.

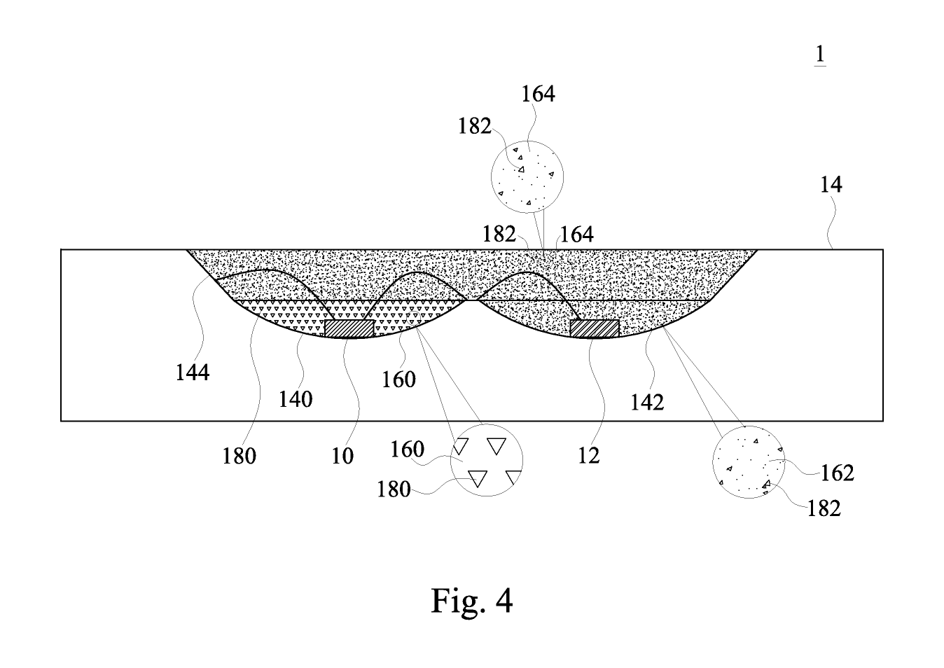

With reference to FIG. 4 for a cross-sectional view of another preferred embodiment of the present invention, the white-light LED package structure 1 for enhancing mixed light effect is designed with different geometric shapes to achieve the uniform mixed light effect and improve the light performance. The frame structure 14 is designed with a circular arc shape, and includes the first containing portion 140 and the second containing portion 142, both being downwardly tapered cup structures with a cross-section in a circular arc shape, and provided for installing the first light emitting chip 10 and second light emitting chip 12. The circular arc shaped design can adjust the light exiting angle of the two LED chips. The first light emitting chip 10 provides a light source with a wavelength of 400 nm˜500 nm. After the first colloid 160 is filled into the first containing portion 140, some of the light source emitted from the first light emitting chip 10 are excited by the green-light phosphor 180 to change the light source with a wavelength of 400 nm˜500 nm to a light source with a wavelength of 490 nm˜600 nm, and the second light emitting chip 12 provides a light source with a wavelength of 600 nm˜700 nm. After the second colloid 162 is filled into the second containing portion 142, and the dispersant 182 is doped into the second colloid 162, diffusions can be produced. The lights with the three different wavelengths are projected from the first containing portion 140 and the second containing portion 142 into the light mixing area 144, and after a mixed light is formed in the light mixing area 144, a white-light dot light source is produced. In addition, the encapsulating colloid 164 of the light mixing area 144 can be doped with the dispersant 182 to provide a better light mixing effect and a more uniform white light.

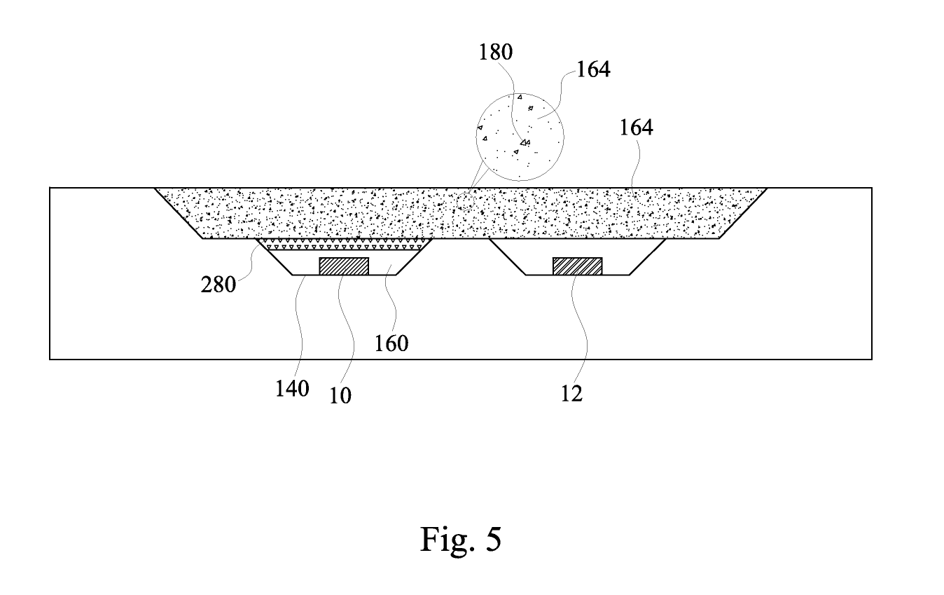

With reference to FIG. 5 for a cross-sectional view of another preferred embodiment of the present invention, a remote phosphor coating method or a conformal coating method can be adopted to dope the red-light phosphor 280 above the first colloid 160. The first colloid 160 is not doped in this preferred embodiment. The encapsulating colloid 164 is doped with a dispersant 182 and green-light phosphor 180. With reference to Tables 1 and 2 for the illumination performance of this preferred embodiment, the red-light phosphor 280 is doped into the first colloid 160 by the remote phosphor coating method, so that the red-light phosphor 280 is formed onto a thin layer at the cup opening position of the first containing portion 140, and the light emitted from the first light emitting chip 10 is excited by the red-light phosphor 280 when passing through the thin layer of the red-light phosphor 280 to form lights of two different wavelengths to enhance the light output of a white light LED. After the light emitted by the first light emitting chip 10 is excited by the red-light phosphor 280, a portion of the light changes its wavelength from 400 nm˜500 nm to 600 nm˜700 nm. Please refer to Table 1 below, in this preferred embodiment, color rendering index (CRI) value of 90 can be achieved. The CRI performance of this embodiment is enhanced by 5-15% relative to the prior art. The intensity of blue and green light emitted by the embodiment in FIG. 5 is also the highest relative to the prior art and the embodiment in FIG. 1.

TABLE 1

| Embodiment | CRI Value |
|---|---|
| Prior Art | 80 |
| Embodiment in FIG. 1 | 87 |
| Embodiment in FIG. 5 | 90 |

In summation of the description above, the present invention has the following advantages:

1. The phosphor is arranged above the light source for exciting the phosphor, not only achieving the effect of converting the light energy into lights of different wavelengths, but also avoiding blocking the light of other light sources to improve the color rendering index of the white light and achieve the effects of enhancing light emission efficiency, and saving power consumption.

2. A containing groove is provided for containing the LED chip, and each containing groove is dispensed and coated with phosphor, which can be mass produced easily to simplify the complicated manufacturing process and improve the low yield rate of the prior art.

3. An optical design based on the shape of the frame is adopted to improve the light mixing effect and provide a white-light LED with the features of higher color rendering index, better uniformity and lower power consumption.

What is claimed is:

1. An white-light LED package structure for enhancing mixed light effect, comprising:
one first light emitting chip, for providing a light source with a wavelength of 400 nm˜500 nm;
one second light emitting chip, for providing a light source with a wavelength of 600 nm˜700 nm;
a frame structure, for containing and installing the first light emitting chip and the second light emitting chip, such that after lights emitted from the first light emitting chip and the second light emitting chip are mixed, a white-light dot light source for emitting light is formed, and the frame structure comprising:
a first containing portion, being a downwardly tapered cup structure provided for installing the first light emitting chip;
a second containing portion, being a downwardly tapered cup structure, for installing the second light emitting chip;
a spacing portion, disposed between the first containing portion and the second containing portion, for bonding and installing the first light emitting chip and the second light emitting chip; and
a light mixing area, for forming the white-light dot light source after the lights emitted from the first light emitting chip and the second light emitting chip are mixed in the light mixing area;
a first colloid, filled into the first containing portion, for encapsulating the first light emitting chip;
a second colloid, filled into the second containing portion, for covering the second light emitting chip; and
an encapsulating colloid, doped with a green-light phosphor, packaged and filled into the light mixing area, and disposed on the first colloid and the second colloid,
wherein a red light phosphor is doped in the first containing portion between the first colloid and the encapsulating colloid such that after the light emitted by the first light emitting chip is excited by the red-light phosphor, a portion of the light changes its wavelength of 400 nm˜500 nm to a wavelength of 600 nm˜700 nm.

2. The white-light LED package structure for enhancing mixed light effect as recited in claim 1, wherein the first containing portion and the second containing portion have a downwardly tapered trapezoid cross-section.

3. The white-light LED package structure for enhancing mixed light effect as recited in claim 1, wherein the second colloid is doped with a dispersant.

4. The white-light LED package structure for enhancing mixed light effect as recited in claim 2, wherein the second colloid is doped with a dispersant.

5. The white-light LED package structure for enhancing mixed light effect as recited in claim 1, wherein the encapsulating colloid is doped with a dispersant.

6. The white-light LED package structure for enhancing mixed light effect as recited in claim 2, wherein the encapsulating colloid is doped with a dispersant.
